(19) United States
(12) Patent Application Publication
(10) Pub. No.: US 2025/0305150 A1
(43) Pub. Date: Oct. 2, 2025

(54) ETCHANT COMPOSITION FOR METAL LAYER CONTAINING SILVER AND PREPARATION METHOD THEREOF

(71) Applicants: ENF Technology Co., Ltd., Gyeonggi-do (KR); Samsung Display Co., LTD., Gyeonggi-do (KR)

(72) Inventors: Boyeon LEE, Gyeonggi-do (KR); Jaeyeop KIM, Gyeonggi-do (KR); Sehoon KIM, Gyeonggi-do (KR); Heejin PARK, Gyeonggi-do (KR); Jihoon JANG, Gyeonggi-do (KR); Jonghwa LEE, Gyeonggi-do (KR); Jinhyung KIM, Gyeonggi-do (KR); Sok-Ho LEE, Gyeonggi-do (KR); Youngmin KIM, Gyeonggi-do (KR)

(21) Appl. No.: 19/079,711

(22) Filed: Mar. 14, 2025

(30) Foreign Application Priority Data
Mar. 28, 2024 (KR) 10-2024-0042587

(51) Int. Cl. C23F 1/30; C09K 13/06

(52) U.S. Cl. CPC C23F 1/30; C09K 13/06

(57) ABSTRACT

The present invention relates to a composition for selectively etching metal film containing silver (Ag), and a method for producing the same, which can selectively etch the single film of silver (Ag) or a silver alloy, or a multilayer film containing the metal film and an indium oxide film, while preventing damage to an underlying film, residue, and staining.

### TECHNICAL FIELD

The present invention relates to a composition for etching a metal layer containing silver (Ag).

Specifically, the present invention relates to a composition for selectively etching a single film of silver (Ag) or a silver alloy, or a multilayer film comprising the single film and an indium oxide film, and a method for producing the same. This application claims the benefit of priorities to Korean Patent Application No. 10-2024-0042587 filed on Mar. 28, 2024, the entire disclosures of which are incorporated herein by reference.

### BACKGROUND ART

Reflective displays reflect backlight to the front, allowing for reduction of light loss and power consumption. Traditionally, aluminum thin films were mainly used as materials for reflectors or reflective electrodes used in reflective displays. However, as the display industry developed, silver (Ag), a metal with high reflectivity and low resistance, has attracted attention. It is used for realizing low power consumption by forming a transparent indium oxide film on a thin film mainly composed of silver (Ag).

A thin film containing highly reflective silver (Ag) can reflect light from back to the front more efficiently than a white-painted reflector or an aluminum reflector, increasing the illumination by nearly two times. When using a silver film, there is little light loss, and silver (Ag) has low resistance and high luminance compared to other metals, making it suitable for use as a reflector. In addition, as display devices become to have higher resolution and larger in size, silver-containing wiring, which has higher conductivity than aluminum and copper, which are generally used in wiring of thin film transistor substrates, is being used.

Indium (In) oxide films have properties of converting electrical signals into light signals and are generally used as transparent electrically conductive films in various flat panel devices, such as transparent electrodes in liquid crystal displays.

Conventionally, etchants based on nitric acid, phosphoric acid, or acetic acid were mainly used to etch silver (Ag) or silver alloy films. However, when using these etchants, over-etching may occur depending on the flow rate, which may cause short-circuiting of some of wiring containing silver. And, as the number of etching treatments for the silver or silver alloy single film, or a metal layer containing the single film and an indium oxide film, increases, the etching deviation increases significantly, which may cause defects such as staining or damage to the underlying film.

Therefore, research is needed into a composition for selectively etching a metal layer containing silver while simultaneously preventing damage to the underlying film, residue, and staining.

### DETAILED DESCRIPTION OF THE INVENTION

### Technical Problem

The object of the present invention is to provide a composition and a method for manufacturing the same, allowing for uniformly etching a metal layer containing silver (Ag), while minimizing damage to an underlying film, preventing the occurrence of precipitates resulting from the etching process, and minimizing the occurrence of defects such as residues, stains, and over-etching.

### Solution to Problem

In order to solve the above problem, the present invention provides an etchant composition for a metal layer containing silver, comprising:
an inorganic acid;
an inorganic sulfate;
two or more organic sulfur compounds; and
an organic acid,
wherein the inorganic acid and the organic acid do not contain sulfur element, and each of the components satisfies the mathematical formula 1:

$$0.4 \leq \frac{M {W}_{sulfate cation}}{M {W}_{sulfate anion}} * \frac{{M}_{inorganic acid}}{{M}_{organic acid}} \leq 1.0 \qquad [ Mathematical formula 1 ]$$

wherein in mathematical formula 1,
MWsulfate cation is the molar mass of the cation of the substance used as sulfate,
MW_{sulfate anion} is the molar mass of the anion of the substance used as sulfate,
M_{inorganic acid} is the total mole number of inorganic acid in the etchant composition, and
M_{organic acid} is the total mole number of organic acid in the etchant composition.

According to one embodiment, the organic sulfur compound may comprise a compound of chemical formula 1 and a compound of chemical formula 2, and
wherein the weight ratio of the compound of chemical formula 1 and the compound of chemical formula 2 may be 1:1 to 1:4.

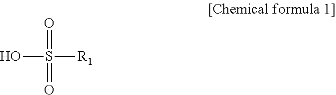

wherein,
R₁ is C₁₋₁₀ alkyl;

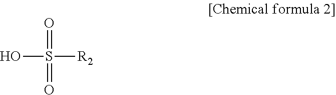

wherein,
R₂ is (C₁₋₁₀ alkyl)benzyl, benzyl, amino(C₁₋₁₀ alkyl) or aminobenzyl.

In addition, for example, R₁ in the chemical formula 1 may be C₁₋₆ alkyl, and R₂ in the chemical formula 2 may be (C₁₋₆ alkyl)benzyl, benzyl, amino(C₁₋₆ alkyl) or aminobenzyl.

More specifically, for example, the compound of the chemical formula 1 may include methanesulfonic acid. In addition, the compound of the chemical formula 2 may include at least one of toluenesulfonic acid, benzenesulfonic acid, taurine, and anilinesulfonic acid.

According to one embodiment, the weight ratio of the inorganic sulfate and the two or more organic sulfur compounds may be 1:1 to 1:2.

The total content of the above organic sulfur compound may be 10 to 30 wt % with respect to the total weight of the composition.

According to one embodiment, the inorganic sulfate may include at least one of sodium hydrogen sulfate, sodium sulfate, ammonium hydrogen sulfate and ammonium sulfate.

According to one embodiment, the inorganic acid may include nitric acid.

According to one embodiment, the organic acid may include at least one of citric acid, acetic acid, succinic acid, glutaric acid, adipic acid, pimelic acid, suberic acid, malic acid, tartaric acid, lactic acid, propionic acid, caproic acid, caprylic acid, phenylacetic acid, benzoic acid, benzenemonocarboxylic acid, nitrobenzoic acid, hydroxybenzoic acid, aminobenzoic acid, diacetic acid, pyruvic acid, gluconic acid, glycolic acid, nitrilotriacetic acid, ethylenediaminetetraacetic acid, alanine, aminobutyric acid, glycine, and iminodisuccinic acid.

According to another embodiment of the present invention, a method for preparing an etchant composition for a metal layer containing silver is provided, comprising mixing
1 to 30 wt % of an inorganic acid;
5 to 30 wt % of an inorganic sulfate;
10 to 30 wt % of two or more organic sulfur compounds;
20 to 60 wt % of an organic acid; and
the remainder of water,
wherein the inorganic acid and the organic acid do not contain sulfur element, and
each of the components satisfies the mathematical formula 1:

$$0.4 \leq \frac{M {W}_{sulfate cation}}{M {W}_{sulfate anion}} * \frac{{M}_{inorganic acid}}{{M}_{organic acid}} \leq 1.0 \qquad [ Mathematical formula 1 ]$$

wherein in mathematical formula 1,
MW_{sulfate cation} is the molar mass of the cation of the substance used as sulfate,
MW_{sulfate anion} is the molar mass of the anion of the substance used as sulfate,
M_{inorganic acid} is the total mole number of inorganic acid in the etchant composition, and
M_{organic acid} is the total mole number of organic acid in the etchant composition.

Specific details of other embodiments according to the present invention are included in the detailed description below.

### Effect of the Invention

According to the etchant composition of the present invention, in the etching process of a metal layer containing silver, damage to the underlying film can be minimized, and etching uniformity can be improved, thereby minimizing the occurrence of defects such as residues, stains, and over-etching.

### BEST MODE FOR CARRYING OUT THE INVENTION

Since the present invention may apply various modifications and have various embodiments, specific embodiments are intended to be described in the specification in detail. However, these descriptions are not intended to limit the present invention to the specific embodiments, but should be understood to include all modifications, equivalents, or substitutions involved in the spirit and scope of the present invention. If it is considered that the detailed descriptions of related known technologies may obscure the gist of the present invention, those descriptions will be omitted.

Unless otherwise specified herein, the expression “from A to B” is used to include the indicated numerical values. Specifically, for example, the expression “from 1 to 2” means not only including 1 and 2, but also all numbers between 1 and 2.

The term “alkyl” as used herein means a linear or branched saturated hydrocarbon radical chain, and examples thereof may include, but are not limited to, methyl, ethyl, n-propyl, isopropyl, n-butyl, isobutyl, t-butyl, n-pentyl, isopentyl, hexyl, and the like.

During the etching process of a semiconductor substrate, the problem of damage to the underlying metal film may occur, and the underlying film may include copper, aluminum, and the like. The present invention is intended to provide an etchant composition capable of improving the etching characteristics of a silver or silver alloy single film as an upper film and a multilayer metal film containing the single film and an indium oxide film while minimizing damage to the underlying metal film regardless of the type of the underlying film.

The etchant composition according to one embodiment of the present invention is for etching a silver (Ag)-containing metal film or a silver alloy film used as a reflector or a thin film transistor (TFT) metal wiring, and or a multilayer film comprising the silver-containing metal film and an indium (In) oxide film used as a transparent electrode of a display device, and the metal film may be an alloy film, a single film, or a multilayer film. For example, the multilayer film may comprise a first layer comprising a metal oxide, a second layer disposed over the first layer and comprising silver or a silver alloy, and a third layer disposed over the second layer and comprising a metal oxide film. For example, the first layer and the third layer of the multilayer film may include an indium tin oxide film. However, the embodiments of the present invention are not limited to the etching of the triple layer as described above and can be used for the etching of various multilayer structures, such as a doble layer structure of a metal oxide film and a silver-containing film. The metal oxide film may refer to an oxide film including metals, such as indium (In), tin (Sn), or a combination thereof. According to one embodiment, the silver alloy may include various forms such as an alloy form containing silver as a main component and other metals such as Nd, Cu, Pb, Nb, Ni, Mo, Ni, Cr, Mg, W, Pa, and Ti, and a nitride, silicide, carbide, or oxide form of silver.

Also, for example, the indium oxide film can be formed as an indium oxide film, specifically, indium zinc oxide (IZO), indium tin oxide (ITO), or a mixture thereof, and can be used as an electrode of a substrate for an image display device.

Hereinafter, an etchant composition for a metal layer containing silver (Ag) according to the present invention will be described in detail.

The present invention provides an etchant composition for a metal layer containing silver comprising an inorganic acid, an inorganic sulfate, two or more organic sulfur compounds, and an organic acid.

The silver-containing metal layer of the present invention includes a single film of silver or a silver alloy, or a multilayer film containing the single film and an indium oxide film.

According to one embodiment, the inorganic acid can act as a primary oxidizing agent that rapidly oxidizes and etches the surface of the metal layer containing silver (Ag). Specifically, by adding inorganic acid, over-erosion of the metal film containing silver or indium oxide can be prevented, thereby controlling the etching rate. The inorganic acid of the present invention does not contain elemental sulfur. Specific examples of inorganic acid include at least one of nitric acid, ammonium nitrate, sodium nitrate, potassium nitrate, and calcium nitrate.

The content of the inorganic acid may be from 1 to 30 wt %, for example, from 3 to 25 wt %, from 5 to 20 wt %, from 10 to 20 wt %, from 15 to 20 wt %, from 5 to 10 wt %, or from 10 to 15 wt %.

According to one embodiment, the inorganic sulfate can act as an etchant. Unless otherwise specified herein, sulfate refers to inorganic sulfate. Specifically, by incorporating the inorganic sulfate, it is possible to prevent residues due to non-etching of the metal layer, loss of wiring due to over-etching, and increased etching deviation.

Inorganic sulfate, which is an inorganic sulfur compound, can effectively etch metals by being included in the etchant composition of the present invention, distinguished from the inorganic acid and the organic sulfur compound described below. Specific examples of the inorganic sulfate may include at least one of sodium hydrogen sulfate (SHS), sodium sulfate (SS), ammonium hydrogen sulfate (AHS), and ammonium sulfate (AS).

The content of inorganic sulfate may include, for example, from 5 to 30 wt %, from 5 to 20 wt %, from 10 to 20 wt %, or from 10 to 15 wt %.

In one embodiment, two or more organic sulfur compounds can act as auxiliary oxidizing agents. Organic sulfur compounds can effectively etch metals by being included in the etchant composition of the present invention, distinguished from the above-mentioned inorganic acids and sulfates. The organic sulfur compound of the present invention is distinguished from sulfate and does not include sulfate, specifically inorganic sulfate.

Specifically, by including two or more organic sulfur compounds, it is possible to prevent problems such as residues due to non-etching of the metal layer, loss of wiring due to over-etching, and increased etching deviation.

The organic sulfur compounds may include, for example, a compound of chemical formula 1 and a compound of chemical formula 2.

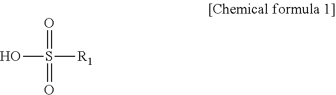

wherein,
R₁ is C₁₋₁₀ alkyl, for example, C₁₋₆ alkyl. For example, R₁ may be methyl, ethyl, propyl, butyl, pentyl or hexyl.

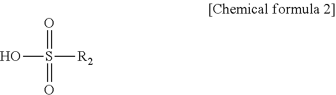

wherein,
R₂ is (C₁₋₁₀ alkyl)benzyl, for example, (C₁₋₆ alkyl)benzyl, benzyl, amino(C₁₋₁₀ alkyl), for example, amino(C₁₋₆ alkyl) or aminobenzyl. For example, R₂ may be methylbenzyl, benzyl, aminoethyl, or aminobenzyl.

The compound of chemical formula 1 may specifically include, for example, methanesulfonic acid. Additionally, the compound of chemical formula 2 may specifically include at least one of toluenesulfonic acid, benzenesulfonic acid, taurine, and anilinesulfonic acid.

According to one embodiment, the weight ratio of the compound of chemical formula 1 to the compound of chemical formula 2 may be from 1:1 to 1:4, for example, from 1:1.5 to 1:3, from 1:1.5 to 1:2, or from 1:2 to 1:3. The total content of the organic sulfur compounds may be from 10 to 30 wt %, for example, from 10 to 25 wt %, from 10 to 20 wt %, from 10 to 15 wt %, from 20 to 25 wt %, or from 15 to 20 wt %, based on the total weight of the composition. The content of the organic sulfur compounds refers to the total sum of the content of the compound of chemical formula 1 and the content of the compound of chemical formula 2.

According to one embodiment, the content ratio of the inorganic sulfate to the organic sulfur compound may be from 1:1 to 1:2, for example, from 1:1 to 1:1.5 by weight.

The functional groups of the inorganic sulfate and organic sulfur compound of the present invention strongly bind to metal ions oxidized by inorganic acids, thereby allowing for stable etching. Specifically, the sulfonic acid functional group can prevent re-adsorption of oxidized metals, reduce residue formation, and weaken penetration into the underlying film. This action suppresses the penetration of the etchant between films, thereby reducing the defect of bias (also called skew) when forming fine wiring and improving the straightness of the wiring.

According to one embodiment, the organic acid can act as a chelating agent or buffer. The organic acid of the present invention can play a role in stabilizing the etchant composition through a chelating reaction between the organic acid and the metal ions during the etching process, thereby preventing the metal ions from being reduced and re-adsorbed on the substrate. Thus, it has the effect of reducing the occurrence of residue after etching.

The organic acid of the present invention does not contain elemental sulfur. In one embodiment, specific examples of organic acid include at least one of citric acid, acetic acid, succinic acid, glutaric acid, adipic acid, pimelic acid, suberic acid, malic acid, tartaric acid, lactic acid, propionic acid, caproic acid, caprylic acid, phenylacetic acid, benzoic acid, benzene monocarboxylic acids, nitrobenzoic acid, hydroxybenzoic acid, aminobenzoic acid, diacetic acid, pyruvic acid, gluconic acid, glycolic acid, nitrilotriacetic acid, ethylenediaminetetraacetic acid, alanine, aminobutyric acid, glycine, and iminodisuccinic acid. For example, by incorporating citric acid as a chelating agent, metal ions can be stabilized. Additionally, the buffer solution may specifically include, for example, acetic acid.

The total content of the organic acid may be from 20 to 60 wt %, for example, from 25 to 50 wt %, from 20 to 40 wt %, from 25 to 35 wt %, from 30 to 45 wt %, from 30 to 40 wt %, from 30 to 35 wt %, or from 35 to 40 wt % based on the total weight of the composition.

According to a specific embodiment, the composition of present invention may contain from 10 to 30 wt %, for example from 15 to 25 wt %, from 15 to 20 wt %, or from 20 to 25 wt %, of citric acid; and from 5 to 30 wt %, for example from 5 to 20 wt %, from 10 to 20 wt %, or from 15 to 20 wt %, of acetic acid, based on the total weight of the composition.

In one embodiment, the composition according to the present invention may not comprise a dicarbonyl compound comprising nitrogen. Specific examples of such compound include imidazolidine-2,4-dione, glutamic acid, pyroglutamic acid, asparagine, aspartic acid, hippuric acid, iminodiacetic acid, succinimide, glutarimide.

According to one embodiment, each of the components of the present invention satisfies the mathematical formula 1:

$$0.4 \leq \frac{M {W}_{sulfate cation}}{M {W}_{sulfate anion}} * \frac{{M}_{inorganic acid}}{{M}_{organic acid}} \leq 1.0 \qquad [ Mathematical formula 1 ]$$

wherein in mathematical formula 1,
MW_{sulfate cation} is the molar mass of the cation of the substance used as sulfate,
MW_{sulfate anion} is the molar mass of the anion of the substance used as sulfate,
M_{inorganic acid} is the total mole number of inorganic acid in the etchant composition, and
M_{organic acid} is the total mole number of organic acid in the etchant composition.

The present invention can improve the etching characteristics of the metal layer containing silver (Ag), by providing a composition satisfying a specific compound type as described above and satisfying mathematical formula 1.

According to one embodiment, the present invention may contain a balance of water such that the total weight of the composition is 100 wt %. The water in the present invention is not particularly limited, but it is preferable deionized water, and more preferably deionized water having a resistivity value of 18 MΩ·cm or more, which indicates the degree to which ions have been removed from the water.

Hereinafter, embodiments of the present invention will be described in detail so that those skilled in the art can easily implement the present invention. However, the present invention can be implemented in various forms and is not limited to the embodiments described herein.

### EXAMPLES AND COMPARATIVE EXAMPLES

An etchant composition for metal layer containing silver was prepared with the composition shown in Table 1. The content is expressed in % by weight, and each composition contains the remainder of water.

TABLE 1

| | Inorganic | | | | Mathematical | Organic sulfur | | | | | | | |
|---|---|---|---|---|---|---|---|---|---|---|---|---|---|
| Ex. | acid | | Sulfate | | formula 1 | compound | | | | Organic acid | | | |
| Example 1 | NA | 10 | SHS | 15 | 0.42 | MSA | 5 | pTSA | 15 | CA | 20 | AA | 15 |
| Example 2 | NA | 10 | SHS | 15 | 0.44 | MSA | 5 | pTSA | 15 | CA | 25 | AA | 15 |
| Example 3 | NA | 10 | SHS | 10 | 0.49 | MSA | 5 | pTSA | 15 | CA | 20 | AA | 15 |
| Example 4 | NA | 10 | SHS | 10 | 0.51 | MSA | 5 | pTSA | 15 | CA | 25 | AA | 15 |
| Example 5 | NA | 10 | AHS | 15 | 0.41 | MSA | 5 | pTSA | 15 | CA | 20 | AA | 15 |
| Example 6 | NA | 10 | AHS | 15 | 0.43 | MSA | 5 | pTSA | 15 | CA | 25 | AA | 15 |
| Example 7 | NA | 10 | SS | 15 | 0.89 | MSA | 5 | pTSA | 15 | CA | 20 | AA | 15 |
| Example 8 | NA | 10 | SS | 15 | 0.94 | MSA | 5 | pTSA | 15 | CA | 25 | AA | 15 |
| Example 9 | NA | 10 | AS | 15 | 0.68 | MSA | 5 | pTSA | 15 | CA | 20 | AA | 15 |
| Example 10 | NA | 10 | AS | 15 | 0.72 | MSA | 5 | pTSA | 15 | CA | 25 | AA | 15 |
| Comparative | NA | 10 | SHS | 15 | 0.35 | MSA | 5 | pTSA | 15 | CA | 5 | AA | 15 |
| Example 1 | | | | | | | | | | | | | |
| Comparative | NA | 10 | SHS | 20 | 0.31 | MSA | 5 | pTSA | 15 | CA | 5 | AA | 15 |
| Example 2 | | | | | | | | | | | | | |
| Comparative | NA | 10 | AHS | 15 | 0.27 | MSA | 5 | pTSA | 15 | CA | 5 | AA | 15 |
| Example 3 | | | | | | | | | | | | | |
| Comparative | NA | 10 | AHS | 20 | 0.23 | MSA | 5 | pTSA | 15 | CA | 5 | AA | 15 |
| Example 4 | | | | | | | | | | | | | |
| Comparative | NA | 10 | KS | 15 | 1.07 | MSA | 5 | pTSA | 15 | CA | 30 | AA | 15 |
| Example 5 | | | | | | | | | | | | | |
| Comparative | NA | 10 | CdS | 15 | 1.13 | MSA | 5 | pTSA | 15 | CA | 30 | AA | 15 |
| Example 6 | | | | | | | | | | | | | |
| Comparative | NA | 10 | CuS | 15 | 1.03 | MSA | 5 | pTSA | 15 | CA | 30 | AA | 15 |
| Example 7 | | | | | | | | | | | | | |
| Comparative | NA | 10 | FeS | 15 | 1.01 | MSA | 5 | pTSA | 15 | CA | 30 | AA | 15 |
| Example 8 | | | | | | | | | | | | | |

NA: Niric acid
SHS: Sodium hydrogen sulfate
MSA: Methanesulfonic acid
pTSA: p-Toluenesulfonic acid
CA: Citric acid
AA: Acetic acid
AHS: Ammonium hydrogen sulfate
SS: Sodium sulfate
AS: Ammonium sulfate
KS: Potassium sulfate
CdS: Cadmium sulfate
CuS: Copper sulfate
FeS: Iron sulfate

### Experimental Example 1: Evaluation of Damage, Residue and Precipitation in Underlying Film

In order to evaluate the etching performance of the etchant composition, a triple layer of ITO/Ag/ITO was sequentially formed on a glass substrate (100 mm×100 mm), and then a pattern was formed using a photolithography process to manufacture a specimen. An etching process was performed on a substrate under the same conditions using each etchant composition of the examples and comparative examples. A wet etcher was charged with 10 kg of each etchant composition, and the temperature was set to 40° C., and then the etching characteristics of the prepared specimens were evaluated.

After etching was completed, the occurrence of damage, residue, and precipitates in the etched cross-section of the triple layer of ITO/Ag/ITO was observed using SEM (SU-8010, HITACHI). The evaluation criteria are as follows, and the results are shown in Table 2.

### <Residue Evaluation Criteria>

⊚: No residue
∘: Almost no residue
X: Residue occurrence

### <Precipitate Evaluation Criteria>

⊚: Less than 5
∘: 5 or more but less than 20
Δ: 20 or more but less than 50
X: 50 or more

### Experimental Example 2: Evaluation of Etching Uniformity and Extent of Wiring Loss

Each specimen treated with the etchants of the examples and comparative examples was observed using a scanning electron microscope to measure the uniformity of the resultant wiring.

After etching, the upper photoresist was removed from the substrate using a stripping agent. The pattern uniformity and presence of wiring loss of the silver thin film in the triple-layer specimen were observed using a scanning electron microscope (SEM; model name: SU-8010, HITACHI), and the results are shown in Table 2.

### <Etching Uniformity Evaluation Criteria>

⊚: less than 0.05 μm
∘: 0.05 μm or more but less than 0.1 μm
Δ: 0.1 μm or more but less than 0.2 μm
X: 0.2 μm or more

TABLE 2

| | | | | Etching | Wiring |
|---|---|---|---|---|---|
| | Skew(μm) | Residue | Precipitate | uniformity | loss |
| Example 1 | 0.10 | ⊚ | ⊚ | ⊚ | No |
| Example 2 | 0.10 | ⊚ | ⊚ | ⊚ | No |
| Example 3 | 0.09 | ⊚ | ⊚ | ⊚ | No |
| Example 4 | 0.10 | ⊚ | ⊚ | ⊚ | No |
| Example 5 | 0.11 | ⊚ | ⊚ | ⊚ | No |
| Example 6 | 0.11 | ⊚ | ⊚ | ⊚ | No |
| Example 7 | 0.10 | ⊚ | ⊚ | ⊚ | No |
| Example 8 | 0.10 | ⊚ | ⊚ | ⊚ | No |
| Example 9 | 0.12 | ⊚ | ⊚ | ⊚ | No |
| Example 10 | 0.10 | ⊚ | ⊚ | ⊚ | No |
| Comparative | 0.10 | X | ◯ | ◯ | Yes |
| Example 1 | | | | | |
| Comparative | 0.10 | X | ◯ | ◯ | Yes |
| Example 2 | | | | | |
| Comparative | 0.09 | X | ◯ | ◯ | Yes |
| Example 3 | | | | | |
| Comparative | 0.10 | X | ◯ | ◯ | Yes |
| Example 4 | | | | | |
| Comparative | 0.10 | X | ◯ | X | Yes |
| Example 5 | | | | | |
| Comparative | 0.10 | X | ◯ | X | Yes |
| Example 6 | | | | | |
| Comparative | 0.12 | X | ◯ | X | Yes |
| Example 7 | | | | | |
| Comparative | 0.13 | X | ◯ | X | Yes |
| Example 8 | | | | | |

As shown in Table 2, it was confirmed that all examples in which the value according to mathematical formula 1 was from 0.4 to 1 had excellent etching characteristics.

On the other hand, all comparative examples in which the value according to mathematical formula 1 was outside the range of 0.4 to 1 had slight damage to the underlying film, and residue and wiring loss occurred. In particular, Comparative Example 5 differs from the Examples in that it contains potassium sulfate instead of sodium sulfate. Comparative Example 5 is not included in the scope of the present invention because the value according to mathematical formula 1 is 1.07, and it is confirmed that there are problems with residue, etching uniformity, and wiring loss.

From these results, it can be seen that even when compounds containing elements belonging to the same group in the periodic table are used, etching characteristics are poor if mathematical formula 1 is not satisfied.

As described above, the etchant composition according to the present invention can selectively etch a silver (Ag) or silver alloy-containing metal film used as a reflector or wiring of a display device, and a multilayer film containing an indium (In) oxide film used as a transparent electrode of a display device together with the metal film, thereby suppressing damage to an underlying film and minimizing bias defects and the occurrence of residues or precipitates when forming fine wiring, thereby exhibiting excellent etching characteristics.

While specific parts of the present invention have been described in detail above, it is obvious to those skilled in the art to which the present invention that such specific descriptions are merely preferred embodiments and that the scope of the present invention is not limited thereto. Those skilled in the art to which the present invention pertains will be able to make various applications and modifications within the scope of the present invention based on the above contents. Accordingly, the substantial scope of the present invention is defined by the appended claims and their equivalents.

What is claimed is:

1. An etchant composition for metal layer containing silver, comprising a mixture of:
an inorganic acid;
an inorganic sulfate;
two or more organic sulfur compounds; and
an organic acid,
wherein the inorganic acid and the organic acid do not contain sulfur element, and each of the components satisfies the mathematical formula 1:
$$0.4 \leq \frac{M {W}_{sulfate cation}}{M {W}_{sulfate anion}} * \frac{{M}_{inorganic acid}}{{M}_{organic acid}} \leq 1.0 \qquad [ Mathematical formula 1 ]$$
wherein in mathematical formula 1,
MW_{sulfate cation} is the molar mass of the cation of the substance used as sulfate,
MW_{sulfate anion} is the molar mass of the anion of the substance used as sulfate,
M_{inorganic acid} is the total mole number of inorganic acid in the etchant composition, and
M_{organic acid} is the total mole number of organic acid in the etchant composition.

2. The etchant composition for metal layer containing silver according to claim 1, wherein
the organic sulfur compound comprises a compound of chemical formula 1 and a compound of chemical formula 2, and
the weight ratio of the compound of chemical formula 1 and the compound of chemical formula 2 is 1:1 to 1:4: 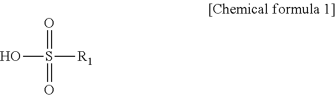
wherein,
R₁ is C₁₋₁₀ alkyl; 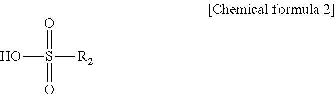
wherein,
R₂ is (C₁₋₁₀ alkyl)benzyl, benzyl, amino(C₁₋₁₀ alkyl) or aminobenzyl.

3. The etchant composition for metal layer containing silver according to claim 2, wherein
R₁ in the chemical formula 1 is C₁₋₆ alkyl, and
R₂ in the chemical formula 2 is (C₁₋₆ alkyl)benzyl, benzyl, amino(C₁₋₆ alkyl) or aminobenzyl.

4. The etchant composition for metal layer containing silver according to claim 2, wherein the compound of the chemical formula 1 comprises methanesulfonic acid.

5. The etchant composition for metal layer containing silver according to claim 2, wherein the compound of the chemical formula 2 comprises at least one of toluenesulfonic acid, benzenesulfonic acid, taurine, and anilinesulfonic acid.

6. The etchant composition for metal layer containing silver according to claim 1, wherein the weight ratio of the inorganic sulfate and the two or more organic sulfur compounds is from 1:1 to 1:2.

7. The etchant composition for metal layer containing silver according to claim 1, wherein the inorganic sulfate comprises at least one of sodium hydrogen sulfate, sodium sulfate, ammonium hydrogen sulfate and ammonium sulfate.

8. The etchant composition for metal layer containing silver according to claim 1, wherein the inorganic acid comprises nitric acid.

9. The etchant composition for metal layer containing silver according to claim 1, wherein the organic acid comprises at least one of citric acid, acetic acid, succinic acid, glutaric acid, adipic acid, pimelic acid, suberic acid, malic acid, tartaric acid, lactic acid, propionic acid, caproic acid, caprylic acid, phenylacetic acid, benzoic acid, benzenemonocarboxylic acid, nitrobenzoic acid, hydroxybenzoic acid, aminobenzoic acid, diacetic acid, pyruvic acid, gluconic acid, glycolic acid, nitrilotriacetic acid, ethylenediaminetetraacetic acid, alanine, aminobutyric acid, glycine, and iminodisuccinic acid.

10. A method for preparing an etchant composition for metal layer containing silver, comprising mixing:
1 to 30 wt % of an inorganic acid;
5 to 30 wt % of an inorganic sulfate;
10 to 30 wt % of two or more organic sulfur compounds;
20 to 60 wt % of an organic acid; and
the remainder of water,
wherein the inorganic acid and the organic acid do not contain sulfur element, and
each of the components satisfies the mathematical formula 1:
$$0.4 \leq \frac{M {W}_{sulfate cation}}{M {W}_{sulfate anion}} * \frac{{M}_{inorganic acid}}{{M}_{organic acid}} \leq 1.0 \qquad [ Mathematical formula 1 ]$$
wherein in mathematical formula 1,
MW_{sulfate cation} is the molar mass of the cation of the substance used as sulfate,
MW_{sulfate anion} is the molar mass of the anion of the substance used as sulfate,
M_{inorganic acid} is the total mole number of inorganic acid in the etchant composition, and
M_{organic acid} is the total mole number of organic acid in the etchant composition.
